(19) United States
(12) Patent Application Publication
(10) Pub. No.: US 2025/0331395 A1
(43) Pub. Date: Oct. 23, 2025

(54) DISPLAY DEVICE AND MANUFACTURING METHOD THEREOF

(71) Applicant: Samsung Display Co., Ltd., Yongin-Si (KR)

(72) Inventor: Ki Tae KIM, Yongin-si (KR)

(21) Appl. No.: 18/934,242

(22) Filed: Nov. 1, 2024

(30) Foreign Application Priority Data
Apr. 22, 2024 (KR) 10-2024-0053394

(51) Int. Cl. H10K 59/80; H10K 59/12; H10K 59/131; H10K 59/95; H10K 102/00

(52) U.S. Cl. CPC H10K 59/873; H10K 59/1201; H10K 59/131; H10K 59/95; H10K 2102/311

(57) ABSTRACT

A display device includes a display panel including a first surface and a second surface and displaying an image; a substrate disposed on the second surface of the display panel and including a first substrate surface and a side surface that intersect; a flexible circuit board connected to a portion of the display panel; a pad unit electrically connecting the flexible circuit board and the display panel; and a protective layer disposed on one surface of the flexible circuit board, wherein the one surface of the flexible circuit board is a surface of the flexible circuit board facing the display panel, and the protective layer covers at least a portion of the first substrate surface and the side surface.

### CROSS-REFERENCE TO RELATED APPLICATION

This application claims priority to and the benefit of Korean Patent Application No. 10-2024-0053394 filed in the Korean Intellectual Property Office on Apr. 22, 2024, the entire contents of which are incorporated herein by reference.

### BACKGROUND

### 1. Field

The present disclosure relates to a display device and a manufacturing method thereof.

### 2. Description of the Related Art

With the development of information technology, a display device that connects users to information has come to play a more central role in users' daily lives. Accordingly, research and development for display devices are continuously being conducted.

In general, a display device may include a display panel on which a plurality of pixels are disposed and a driving integrated circuit (IC) connected to a portion of the display panel to drive the pixels. The driving integrated circuit can generate driving signals and provide them to the pixels.

The driving integrated circuit may be mounted on a flexible printed circuit board (FPCB), and a portion of the flexible printed circuit board may be connected (or electrically connected) to a portion of the display panel through a pad unit disposed on the display panel.

### SUMMARY

One aspect of the present disclosure is to provide a display device and a manufacturing method thereof that can reduce the penetration of impurities (e.g., moisture) into an area (e.g., pad unit) that connects (or electrically connects) the flexible printed circuit board and the display panel.

A display device according to an embodiment of the present disclosure includes a display panel including a first surface and a second surface and displaying an image; a substrate disposed on the second surface of the display panel and including a first substrate surface intersecting a side surface of the substrate; a flexible circuit board connected to a portion of the display panel; a pad unit electrically connecting the flexible circuit board and the display panel; and a protective layer disposed on one surface of the flexible circuit board, wherein the one surface of the flexible circuit board is a surface of the flexible circuit board facing the display panel, and the protective layer covers at least a portion of the first substrate surface and the side surface.

According to an embodiment, the display device may include a first area, a second area, and a bending area disposed between the first area and the second area, the display panel is bendable in the bending area, and the substrate is absent from the bending area.

According to an embodiment, the display device may further include a bending protective layer disposed on the first surface, wherein at least a portion of the bending protective layer may overlap the substrate.

According to an embodiment, the substrate may contact a portion of the second surface.

According to an embodiment, the second surface may be a surface opposite to a surface on which an image of the display panel is displayed.

According to an embodiment, the display device may further include a conductive adhesive layer disposed on the one surface of the flexible circuit board, wherein the conductive adhesive layer may contact the flexible circuit board and the display panel, the protective layer may overlap at least a portion of the conductive adhesive layer, and the first substrate surface may be a surface opposite to a surface of the substrate that contacts the display panel.

According to an embodiment, the protective layer may have a portion that extends from the flexible circuit board beyond the first substrate surface by a protrusion height, measured in a direction perpendicular to a plane on which the substrate is disposed.

According to an embodiment, the protrusion height may be no less than 20 μm and no more than 60 μm.

According to an embodiment, the display device may further include a coating layer disposed on the one surface of the flexible circuit board, wherein the protective layer may cover at least a portion of the coating layer.

According to an embodiment, the spacer may further include a spacer disposed on the first substrate surface, wherein the spacer may contact less than all of the first substrate surface.

According to an embodiment, the display device may further include a spacer disposed on the first substrate surface and having a surface that extends farther from the first substrate surface than the protrusion height.

According to an embodiment, the display device may further include a barrier layer disposed on the second surface of the display panel; and a plate disposed on the barrier layer and positioned to avoid contacting the plate.

A manufacturing method of a display device according to an embodiment of the present disclosure includes providing a display panel having a first surface and a second surface; attaching a base substrate to the second surface of a display panel, the base substrate having a first substrate surface and a side surface that intersect; attaching a flexible circuit board to the display panel; and forming a protective layer on the flexible circuit board, wherein the forming the protective layer includes applying a resin on the flexible circuit board to cover at least a portion of a first substrate surface of the base substrate and the side surface of the base substrate.

According to an embodiment, the display device may include a first area, a second area, and a bending area disposed between the first area and the second area, wherein the display panel is bendable in the bending area, the second surface is a surface opposite to a surface on which an image of the display panel is displayed, the first substrate surface is a surface of the substrate that is opposite to a surface that contacts the display panel, and attaching the base substrate includes putting the base substrate in contact with the second surface of the display panel.

According to an embodiment, the method may also include using a dispenser to apply the resin, and positioning a nozzle of the dispenser to align with a plane of the side surface.

According to an embodiment, the method may also include using a dispenser to apply the resin, and positioning a nozzle of the dispenser to be spaced apart from a plane of the side surface by less than 150 km.

According to an embodiment, the manufacturing method may further include removing at least a portion of the base substrate by irradiating the base substrate with a laser, and directing the laser at either a boundary between the bending area and the second area or the second area.

According to an embodiment, the method may also include forming a groove on the base substrate with the laser, wherein a depth of the groove may be less than half of a thickness of the base substrate.

According to an embodiment, the manufacturing method may further include removing less than all of the base substrate, and leaving a portion of the base substrate intact in the second area.

According to an embodiment, the manufacturing method may further include forming a spacer on the base substrate that remains in the second area, such that the spacer covers a different portion of the base substrate from the protective layer.

According to an embodiment of the present disclosure, a display device and a manufacturing method thereof capable of reducing the penetration of impurities (e.g., moisture) into an area (e.g., pad unit) that connects (or electrically connects) a flexible printed circuit board and a display panel.

### BRIEF DESCRIPTION OF THE DRAWINGS

FIG. 1 is a schematic plan view of a display device according to an embodiment.

FIG. 2 is a schematic cross-sectional view taken along a line A-A′ of FIG. 1 according to an embodiment.

FIG. 3 is a schematic cross-sectional view of a display panel according to an embodiment.

FIGS. 4 and 5 are schematic cross-sectional views taken along a line B-B′ of FIG. 1 according to an embodiment.

FIG. 6 is a schematic flowchart of a manufacturing method of a display device according to an embodiment.

FIGS. 7, 8, 9, 10, 11, and 12 are schematic cross-sectional views of each process step according to a manufacturing method according to an embodiment.

### DETAILED DESCRIPTION OF EMBODIMENTS

It will be apparent to those skilled in the art that various modifications and variations can be made in the present disclosure without departing from the spirit or scope of the disclosure, and specific embodiments are exemplified in the drawings and explained in the detailed description. Thus, it is intended that the present invention covers the modifications and variations of this invention provided they come within the scope of the present invention and their equivalents.

The terms, ‘first’, ‘second’ and the like may be simply used for description of various constituent elements, but those meanings may not be limited to any order or priority. The above terms are used only for distinguishing one constituent element from other constituent elements. For example, a first constituent element may be referred to as a second constituent element and similarly, the second constituent element may be referred to as the first constituent element within the scope of the appended claims. When explaining the singular, unless explicitly described to the contrary, it may be interpreted as the plural meaning.

In the specification, the word “comprise” or “has” is used to specify existence of a feature, a process, an operation, a constituent element, a part, or a combination thereof, and it will be understood that existence or additional possibility of one or more other features, processes, operations, constituent elements, parts, or combinations thereof are not excluded in advance. In addition, it will be understood that when an element such as a layer, film, area, or substrate is referred to as being “on” another element, it can be directly on the other element or intervening elements may also be present. In the specification, it will be understood that when an element such as a layer, film, area, or substrate is referred to as being disposed “on” another element, the disposed direction is not limited to an upper direction and include a side portion direction or a lower direction. In contrast, it will be understood that when an element such as a layer, film, area, or substrate is referred to as being “beneath” another element, it can be directly beneath the other element or intervening elements may also be present.

The present disclosure relates to a display device and a manufacturing method of the display device. Hereinafter, a display device and a manufacturing method of the display device according to embodiments will be described with reference to the accompanying drawings.

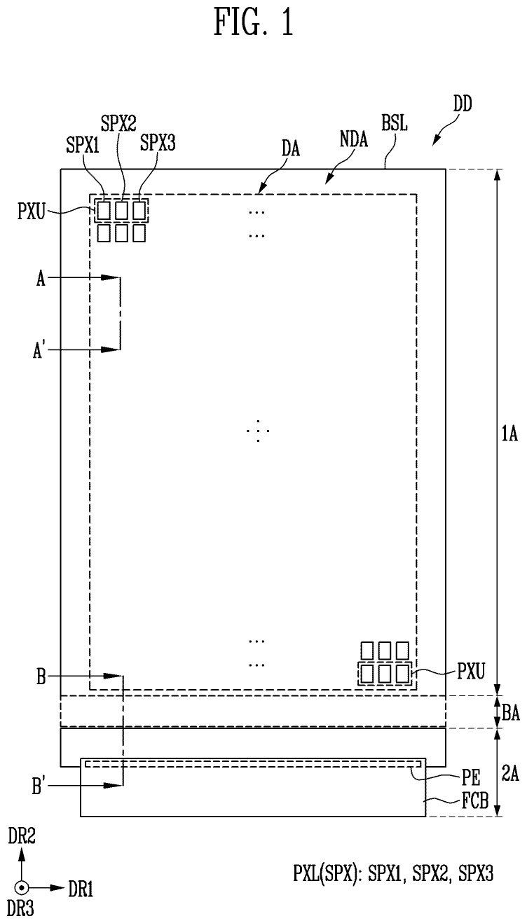

First, the display device DD will be described with reference to FIGS. 1 to 5. FIG. 1 is a schematic plan view of a display device according to an embodiment.

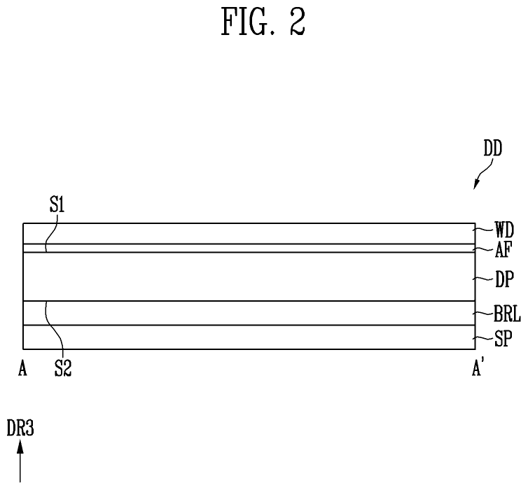

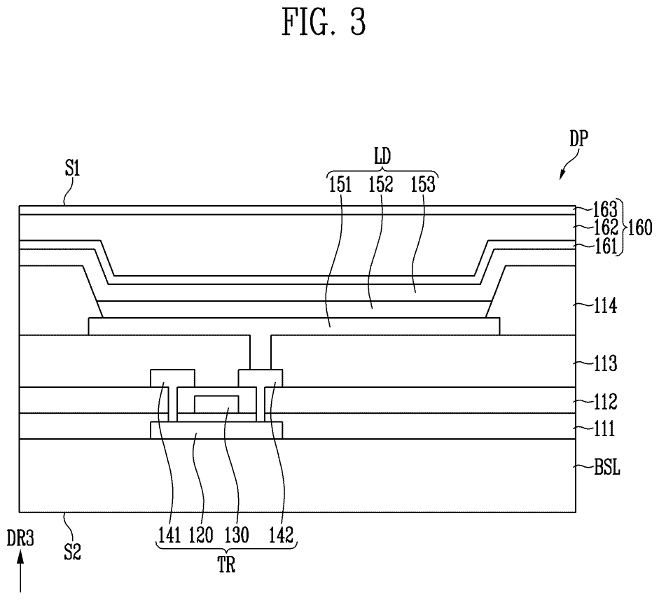

Referring to FIG. 1, the display device DD is configured to emit light. The display device DD may include a light emitting element LD (see FIG. 3) and may include a display panel DP (see FIG. 2) that displays an image. According to an embodiment, the display device DD may be a device that displays moving images or still images. The display device DD can be used as a display screen of not only portable electronic devices such as a mobile phone, a smart phone, a tablet personal computer (tablet PC), a smart watch, a watch phone, a mobile communication terminal, an electronic notebook, an electronic book, a portable multimedia player (PMP), a navigation, an ultra mobile PC (UMPCs), and the like, but also various products such as a television, a laptop, a monitor, a billboard, an internet of things (IoT), and the like. However, an application field of the display device DD is not limited to a specific example.

The display device DD may be formed in a rectangular plane having a short side in the first direction DR1 and a long side in the second direction DR2 crossing the first direction DR1. An edge where the short side of the first direction DR1 and the long side of the second direction DR2 meet may include a right angle or be rounded to have a predetermined curvature. The planar shape of the display device DD is not limited to a quadrangle, and may be formed in other polygonal or round shape such as a circle or an ellipse. The display device DD may be formed to be flat, but is not limited thereto. For example, the display device DD may include curved portions formed at left and right ends and having a constant curvature or a changing curvature.

In the present disclosure, the first direction DR1 may be a row direction of the pixel PXL and may be referred to herein as a “horizontal” direction. The second direction DR2 may be a column direction of the pixel PXL. The second direction DR2 may be perpendicular to the first direction DR1. The third direction DR3 may be referred to as a “display direction” of the display device DD or a normal direction of a plane on which a base layer BSL is disposed.

The display device DD may include a display area DA and a non-display area NDA. The non-display area NDA may refer to an area other than the display area DA. The non-display area NDA may surround at least a portion of the display area DA.

The display area DA may be where the pixels PXL are disposed. The non-display area NDA may be an area free of pixel PXL. A flexible circuit board FCB including a driving circuit, lines, and a pad unit where pads are disposed connected to the pixel PXL of the display area DA, may be disposed in the non-display area NDA. The flexible circuit board FCB may be connected (or electrically connected) to a portion of the display panel DP in one area of the display panel DP through a conductive adhesive layer PE disposed on the display panel DP to generate driving signals, thereby applying it to the pixels PXL of the display panel DP.

The display device DD (or display panel DP) may have a first area 1A, a second area 2A, and a bending area BA. For example, the first area 1A may include a display area DA, and the second area 2A may be a non-display area.

In one embodiment, the second area 2A may be disposed on one side of the first area 1A and may be spaced apart from the first area 1A. For example, the second area 2A may be disposed spaced apart from the first area 1A in a direction opposite to the second direction DR2.

The bending area BA may be disposed between the first area 1A and the second area 2A. The bending area BA may be bent along a bending axis extending in the first direction DR1 that intersects the second direction DR2. The bending area BA may be an area where the display device DD (or display panel DP) can be bent. The display device DD may be flexibly formed to be curved, warped, bent, folded, or rolled.

According to an embodiment, the pixel PXL (or sub-pixels SPX) may include a first sub-pixel SPX1, a second sub-pixel SPX2, and a third sub-pixel SPX3. At least one of the first sub-pixel SPX1, the second sub-pixel SPX2, and the third sub-pixel SPX3 may form one pixel unit PXU capable of emitting light of various colors. In FIG. 1, it is illustrated that each of the pixel PX includes three sub-pixels SPX1, SPX2, and SPX3, that is, the first sub-pixel SPX1, the second sub-pixel SPX2, and the third sub-pixel SPX3, but embodiments of the present disclosure are not limited thereto.

According to an embodiment, the pixels PXL (or sub-pixels SPX) may be arranged according to a stripe or a PENTILE™ arrangement structure. However, the present disclosure is not necessarily limited thereto.

The first sub-pixel SPX1 may emit a first light, the second sub-pixel SPX2 may emit a second light, and the third sub-pixel SPX3 may emit a third light. Here, the first light may be light of a red wavelength band, the second light may be light of a green wavelength band, and the third light may be light of a blue wavelength band. The red wavelength band may be a wavelength band of approximately 600 nm to 750 nm, the green wavelength band may be a wavelength band of approximately 480 nm to 560 nm, and the blue wavelength band may be a wavelength band of approximately 370 nm to 460 nm. However, embodiments of the present disclosure are not limited to these wavelength bands.

Each of the first sub-pixel SPX1, the second sub-pixel SPX2, and the third sub-pixel SPX3 may be a light emitting element that emits light, and may include an inorganic light emitting element such as an inorganic semiconductor or an organic light emitting element. However, the present disclosure is not limited to a particular example, and the following description will be based on an embodiment in which the display device DD includes an organic light emitting element for convenience.

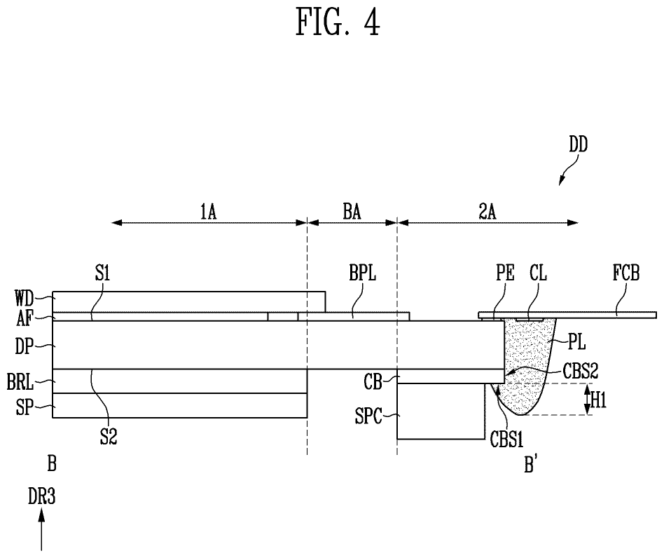

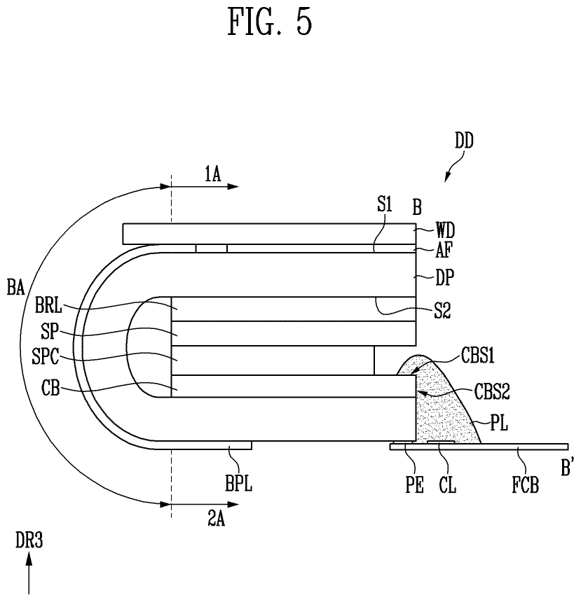

FIG. 2 is a schematic cross-sectional view taken along a line A-A′ of FIG. 1 according to an embodiment. FIG. 3 is a schematic cross-sectional view of a display panel according to an embodiment. FIGS. 4 and 5 are schematic cross-sectional views taken along a line B-B′ of FIG. 1 according to an embodiment. FIG. 5 shows an embodiment in which the display device DD of FIG. 4 is bent in the bending area BA.

Referring to FIGS. 2 and 3, the display device DD may include a display panel DP. The display panel DP may generate images. The display panel DP may include a plurality of pixels PXL for generating an image. The display panel DP may display the generated image on the first surface S1 of the display panel DP such that a viewer would view the image from the top of FIG. 2 and FIG. 3. The first surface S1 of the display panel DP may be a surface on which images of the display panel DP are displayed and may commonly be referred to as the “front surface” of the display panel DP.

The display panel DP may include a base layer BSL, a transistor TR, a light emitting element LD, and an encapsulation layer 160.

The base layer BSL may be a flexible and insulating substrate. For example, the base layer BSL may be a transparent resin substrate. For example, the base layer BSL may be a polyimide (PI) substrate. However, the present disclosure is not limited the substrate material listed above.

The active layer 120 may be disposed on the base layer BSL. The active layer 120 may include an oxide semiconductor, a silicon semiconductor, an organic semiconductor, or the like. For example, oxide semiconductors include at least one oxide selected from the group consisting of indium (In), gallium (Ga), tin (Sn), zirconium (Zr), vanadium (V), hafnium (Hf), cadmium (Cd), germanium (Ge), chromium (Cr), titanium (Ti), and zinc (Zn). Silicon semiconductors may include amorphous silicon, polycrystalline silicon, or the like. The active layer 120 may include a source region, a drain region, and a channel region disposed between the source region and the drain region.

In one embodiment, although not shown in the drawing, a buffer layer may be disposed between the base layer BSL and the active layer 120. The buffer layer can prevent impurities from diffusing into the active layer 120 from the base layer BSL. The buffer layer may include an inorganic insulating material such as a silicon compound or metal oxide. For example, inorganic insulating materials include at least one of silicon oxide (SixOy), silicon nitride (SixNy), silicon oxynitride (SixOyNz), silicon oxycarbide (SixOyCz), silicon carbonitride (SixCyNz), aluminum oxide (AlxOy), aluminum nitride (AlxNy), tantalum oxide (TaxOy), hafnium oxide (HfxOy), zirconium oxide (ZrxOy), and titanium oxide (TixOy). The buffer layer may have a single-layer structure or a multi-layer structure including a plurality of insulating layers.

A first insulating layer 111 may be disposed on the active layer 120. The first insulating layer 111 may cover the active layer 120 on the base layer BSL. The first insulating layer 111 may include an inorganic insulating material such as silicon oxide or metal oxide. The first insulating layer 111 may have a single-layer structure or a multi-layer structure including a plurality of insulating layers.

A gate electrode 130 may be disposed on the first insulating layer 111. The gate electrode 130 may overlap the channel region of the active layer 120. The gate electrode 130 may include a conductive material such as metal, alloy, conductive metal nitride, conductive metal oxide, and transparent conductive material. For example, conductive materials may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), or the like. The gate electrode 130 may have a single-layer structure or a multi-layer structure including a plurality of conductive layers.

A second insulating layer 112 may be disposed on the gate electrode 130. The second insulating layer 112 may cover the gate electrode 130 on the first insulating layer 111. The second insulating layer 112 may include an inorganic insulating material such as silicon oxide and metal oxide. The second insulating layer 112 may have a single-layer structure or a multi-layer structure including a plurality of insulating layers.

A source electrode 141 and a drain electrode 142 may be disposed on the second insulating layer 112. The source electrode 141 and the drain electrode 142 may be connected to the source region and drain region of the active layer 120, respectively. Each of the source electrode 141 and the drain electrode 142 may include a conductive material such as a metal, alloy, conductive metal nitride, conductive metal oxide, transparent conductive material, and the like. Each of the source electrode 141 and the drain electrode 142 may have a single-layer structure or a multi-layer structure including a plurality of conductive layers.

The active layer 120, the gate electrode 130, the source electrode 141, and the drain electrode 142 may form a transistor TR.

A third insulating layer 113 may be disposed on the source electrode 141 and the drain electrode 142. The third insulating layer 113 may include an organic insulating material. For example, the organic insulating material include at least one of acryl resin, epoxy resin, phenol resin, polyamide resin, polyimide resin, and benzocyclobutene (BCB). The third insulating layer 113 may have a multi-layer structure including one or more organic insulating layers and one or more inorganic insulating layers.

The first electrode 151 may be disposed on the third insulating layer 113. The first electrode 151 may be connected to the source electrode 141 or the drain electrode 142. The first electrode 151 may include a conductive material such as metal, alloy, conductive metal oxide, conductive metal nitride, and transparent conductive material. The first electrode 151 may have a single-layer structure or a multi-layer structure including a plurality of conductive layers.

A fourth insulating layer 114 may be disposed on the first electrode 151. The fourth insulating layer 114 may cover a peripheral portion of the first electrode 151 and may include a pixel opening exposing a central portion of the first electrode 151. The fourth insulating layer 114 may include an organic insulating material.

A light emitting layer 152 may be disposed on the first electrode 151. The light emitting layer 152 may be disposed within the pixel opening of the fourth insulating layer 114.

A second electrode 153 may be disposed on the light emitting layer 152. The second electrode 153 may also be disposed on the fourth insulating layer 114. The second electrode 153 may include a conductive material such as metal, alloy, conductive metal oxide, conductive metal nitride, and transparent conductive material. The second electrode 153 may have a single-layer structure or a multi-layer structure including a plurality of conductive layers.

The first electrode 151, the light emitting layer 152, and the second electrode 153 may form a light emitting element LD.

The encapsulation layer 160 may be disposed on the second electrode 153. The encapsulation layer 160 may include at least one inorganic encapsulation layer and at least one organic encapsulation layer. In one embodiment, the encapsulation layer 160 may include a first inorganic encapsulation layer 161 disposed on the second electrode 153, an organic encapsulation layer 162 disposed on the first inorganic encapsulation layer 161, and a second inorganic encapsulation layer 163 disposed on the organic encapsulation layer 162.

The display device DD may further include an adhesive layer AF, a cover member WD, a barrier layer BRL, and a plate SP. The adhesive layer AF and the cover member WD may be disposed on a first surface S1 corresponding to a front surface of the display panel DP. The barrier layer BRL and the plate SP may be disposed on the second surface S2 of the display panel DP. The second surface S2 of the display panel DP may be a surface opposite to the first surface S1 on which an image is displayed and may be a back surface of the display panel DP.

The cover member WD may be disposed on the first surface S1 of the display panel DP and may cover the display panel DP. The cover member WD may be made of a transparent material capable of transmitting an image. For example, the cover member WD may include at least one of glass, sapphire, and plastic. In FIG. 2, the cover member WD may be shown as a single layer, but the present disclosure is not limited thereto and the cover member WD may include a plurality of layers.

The adhesive layer AF may be disposed between the cover member WD and the display panel DP. The adhesive layer AF may attach the cover member WD to the display panel DP.

The adhesive layer AF may include an optically clear adhesive film (OCA). However, the present disclosure is not limited thereto, and the adhesive layer AF may include a conventional bond or adhesive. For example, the adhesive layer AF may include at least one of pressure sensitive adhesive (PSA), optical clear adhesive (OCA), and optical clear resin (OCR).

According to an embodiment, although not shown, functional layers (e.g., optical films, etc.) to improve the light output efficiency of the display device DD may be further disposed between the display panel DP and the adhesive layer AF. In this case, the adhesive layer AF may be disposed on the functional layers to attach the functional layer and the cover member WD.

The barrier layer BRL may be disposed under the display panel DP. For example, the barrier layer BRL may be disposed on the second surface S2 of the display panel DP in a direction opposite to the third direction DR3.

The barrier layer BRL may increase resistance to compressive force due to external pressure. For example, the barrier layer BRL may serve to prevent deformation of the display panel DP. The barrier layer BRL may include a flexible plastic material such as polyimide or polyethylene terephthalate.

According to an embodiment, the barrier layer BRL may be a colored film with low light transmittance. The barrier layer BRL may absorb light incident from the outside. For example, the barrier layer BRL may be a black synthetic resin film.

The plate SP may be disposed under the barrier layer BRL. The plate SP may be disposed on the barrier layer BRL in a negative direction (opposite to the direction of the arrow) in the third direction DR3.

The plate SP may be disposed on a back surface of the display panel DP to support the display panel DP. The plate SP may protect the display panel DP by absorbing shock applied from the outside or blocking foreign substances (e.g., moisture) from penetrating into the display panel DP.

Referring to FIGS. 4 and 5, the barrier layer BRL and the plate SP may be disposed in one area and not in another area. For example, the barrier layer BRL and the plate SP may not be disposed in the bending area BA, but may be disposed in the first area 1A. For example, the barrier layer BRL and the plate SP may not overlap the bending area BA when viewed on a plane, and may overlap the first area 1A when viewed on a plane.

The display device DD according to the present disclosure may further include a bending protective layer BPL, a coating layer CL, a substrate CB, a spacer SPC, and a protective layer PL.

The bending protective layer BPL may be disposed on the first surface S1 of the display panel DP. The bending protective layer BPL may be disposed in the bending area BA. The bending protective layer BPL may overlap the bending area BA of the display panel DP when viewed on a plane. According to an embodiment, the bending protective layer BPL may be further disposed in a portion of the first area 1A and a portion of the second area 2A. According to an embodiment, the bending protective layer BPL may overlap the portion of the first area 1A and the portion of the second area 2A when viewed on a plane.

The bending protective layer BPL may be bent together with the display panel DP in the bending area BA. The bending protective layer BPL may protect the display panel DP from external shock and may minimize bending stress by controlling the stress of the display panel DP when the display panel DP is bent.

The bending protective layer BPL may include at least one of epoxy acrylate resin, polyester acrylate resin, urethane acrylate resin, polyether acrylate resin, silicon acrylate resin, alkyl acrylate resin, epoxy resin, phenol resin, urea resin, melamine resin, and polyurethane resin. However, the present disclosure is not limited to the bending protective layer BPL having at least one of the above-listed materials.

The coating layer CL may be disposed on one surface of the flexible circuit board FCB. For example, the coating layer CL may be disposed on one surface of the flexible circuit board FCB on which the circuit is disposed. One surface of the flexible circuit board FCB on which the coating layer CL is disposed may be a surface of the flexible circuit board FCB facing (or opposing) the display panel DP and the substrate CB.

The coating layer CL may be an insulating layer containing an insulating material. The coating layer CL may cover lines disposed on the flexible circuit board FCB. The coating layer CL may not cover at least a portion of the flexible circuit board FCB. For example, the coating layer CL may not cover the conductive adhesive layer PE, and the flexible circuit board FCB may be electrically connected to the display panel DP through the conductive adhesive layer PE. The conductive adhesive layer PE may be disposed on one surface of the flexible circuit board FCB to contact the flexible circuit board FCB and the display panel DP and to connect electrically the display panel DP and the flexible circuit board FCB.

The substrate CB may be disposed under the display panel DP. For example, the substrate CB may be disposed on the second surface S2 of the display panel DP in a negative direction in the third direction DR3. The substrate CB may be disposed on the second surface S2 of the display panel DP to protect the display panel DP during the manufacturing process of the display device DD. For example, the substrate CB may be a carrier substrate (or carrier film).

The substrate CB may contact the display panel DP in one area and not in another area. For example, in the second area 2A, the substrate CB may contact a portion of the second surface S2 of the display panel DP. For example, in a state in which the display device DD is not bent (i.e., a state shown in FIG. 4 (hereinafter referred to as a first state)), the substrate CB may not contact any portion other than a portion of the second surface S2 of the display panel DP. In the bending area BA and the first area 1A, the substrate CB may expose a surface except for a portion of the second surface S2 that contacts the display panel DP. For example, the substrate CB may not be disposed in the bending area BA and at least a portion of the first area 1A. For example, in the first state, the substrate CB may not overlap the bending area BA and at least a portion of the first area 1A when viewed on a plane.

According to an embodiment, the substrate CB may overlap at least a portion of the bending protective layer BPL when viewed on a plane. However, the present disclosure is not limited thereto. When the bending protective layer BPL is not formed in the first area 1A and the second area 2A, the substrate CB may not overlap the bending protective layer BPL on a plane.

The spacer SPC may be disposed on the substrate CB. For example, the spacer SPC may be disposed on the first substrate surface CBS1 of the substrate CB in the third direction DR3. A first substrate surface CBS1 of the substrate CB may be a surface opposite to the surface where the substrate CB and the display panel DP contact.

The spacer SPC may be placed in one area and not in another area. For example, in the first state, the spacer SPC may be disposed in the second area 2A. For example, in the first state, the spacer SPC may be present in the second area 2A when viewed on a plane. For example, in the first state, the spacer SPC may be absent from the bending area BA and at least a portion of the first area 1A. For example, in the first state, the spacer SPC may be absent from the bending area BA and at least a portion of the first area 1A.

The spacer SPC may expose one area of the substrate CB. The spacer SPC may contact less than all of a surface of the substrate CB. In the first state, the spacer SPC may overlap a portion of the substrate CB, and may not overlap the remaining portions of the substrate CB.

The spacer SPC may have a thickness (or height) that is no less than 80 μm and no greater than 300 μm. According to an embodiment, the spacer SPC may have a thickness (or height) that is no less than 100 μm and no greater than 300 μm. According to an embodiment, the spacer SPC may have a thickness (or height) that is no less than 125 μm and no greater than 300 μm. Hereinafter, the thickness (or height) of one component may be defined in the third direction DR3.

The spacer SPC may have the above-described thickness range, and when the display device DD is bent, one component (e.g., the protective layer PL) of the display device DD may not contact the plate SP.

At least a portion of the protective layer PL may be disposed on one surface of the flexible circuit board FCB. For example, at least a portion of the protective layer PL may be disposed on the surface of the flexible circuit board FCB on which the circuit is disposed. For example, at least a portion of the protective layer PL may be disposed on a surface of the flexible circuit board FCB facing the display panel DP. For example, at least a portion of the protective layer PL may be disposed on a plane where the conductive adhesive layer PE and the coating layer CL are disposed.

The protective layer PL may be disposed on the first substrate surface CBS1 and the second substrate surface CBS2 of the substrate CB. The second substrate surface CBS2 may be a surface defined as a side surface of the substrate CB, and may be a surface forming substantially the same plane as the side surface of the display panel DP. The protective layer PL may overlap the first substrate surface CBS1 of the substrate CB when viewed on a plane. The protective layer PL may cover at least a portion of the first substrate surface CBS1 and the second substrate surface CBS2. The protective layer PL may cover at least a portion of the flexible circuit board FCB and a side surface of the display panel DP.

The protective layer PL may cover just one of two side surfaces of the substrate CB. For example, the protective layer PL may cover the second substrate surface CBS2 of the substrate CB but may not cover the surface opposite to the second substrate surface CBS2. The surface opposite to the second substrate surface CBS2 may be a surface of the substrate CB substantially parallel to the second substrate surface CBS2. The surface opposite to the second substrate surface CBS2 may not contact any layer when the device DD is in a flat state.

According to an embodiment, the protective layer PL may not contact the spacer SPC. According to an embodiment, the protective layer PL and the spacer SPC are on different parts of the substrate CB. According to an embodiment, the protective layer PL may not overlap at least a portion of the bending protective layer BPL when viewed on a plane. According to an embodiment, the protective layer PL may overlap at least a portion of the conductive adhesive layer PE. According to an embodiment, the protective layer PL may overlap at least a portion of the coating layer CL when viewed on a plane. According to an embodiment, the protective layer PL may cover at least a portion of the coating layer CL.

The protective layer PL may include at least one of a thermosetting material or a photocuring material. The photocurable material may include an ultraviolet curable resin. For example, the photocurable material may include at least one of epoxy acrylate resin, polyester acrylate resin, urethane acrylate resin, polyether acrylate resin, silicon acrylate resin, and alkyl acrylate resin. For example, the thermosetting material may include at least one of epoxy resin, phenol resin, urea resin, melamine resin, and polyurethane resin. However, the present disclosure is not limited thereto, and the protective layer PL may include various insulating materials.

The protective layer PL may prevent foreign substances (e.g., moisture) from penetrating into an area where the flexible circuit board FCB and the display panel DP are connected. The protective layer PL may prevent foreign substances (e.g., moisture) from penetrating into the pad unit where the display panel DP and the flexible circuit board FCB are connected. For example, the protective layer PL may prevent foreign substances (e.g., moisture) from penetrating into a portion (hereinafter defined as a compressed portion) of the conductive adhesive layer PE that connects the display panel DP and the flexible circuit board FCB.

The protective layer PL may have a bump that extends from a surface of the substrate CB by a protrusion height H1, as measured from a surface of the substrate CB. In an embodiment, the protective layer PL may extend beyond the first substrate surface CBS1 by the protrusion height H1 in a direction perpendicular to the plane on which the substrate CB is disposed. The protrusion height H1 may be the difference between the distance from the flexible circuit board FCB to the peak of the protective layer PL and the distance from the flexible circuit board FCB to the first substrate surface CBS1, wherein the distance is measured in the third direction DR3.

The protrusion height H1 may be smaller than the thickness (or height) of the spacer SPC. According to an embodiment, the protrusion height H1 may be no less than 10 μm and no greater than 60 μm. According to an embodiment, the protrusion height H1 may be no less than 20 μm and no greater than 60 μm. According to an embodiment, the protrusion height (H1) may be no less than 20 am and no greater than 40 μm.

The protrusion height H1 may be smaller than the thickness (or height) of the spacer SPC. This way, even if the display panel DP is bent, the protective layer PL may not contact the plate SP. For example, when the display panel DP is bent as shown in FIG. 5 (hereinafter referred to as the second state), the protective layer PL may be physically spaced apart from the plate SP. When the protective layer PL contacts the plate SP, noise may be generated when driving the display device DD. However, in the display device DD according to the present disclosure, the height of the spacer SPC may be larger than the protrusion height H1, so the protective layer PL may not contact the plate SP. This way, a risk of generating noise in the display device DD is lowered.

In the display device DD according to the present disclosure, the substrate CB may not be completely removed (e.g., peeled off) during the manufacturing process of the display device DD, and a portion of the substrate CB may remain in the display device DD. The protective layer PL may overlap the first substrate surface CBS1 of the substrate CB when viewed on a plane, and the protective layer PL may reduce a risk of foreign substances (e.g., moisture) penetrating into the compressed portion.

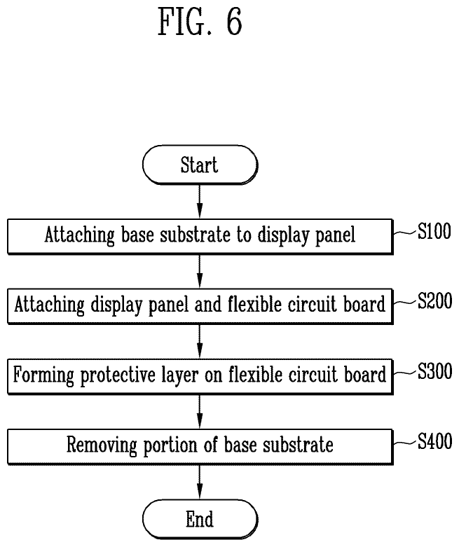

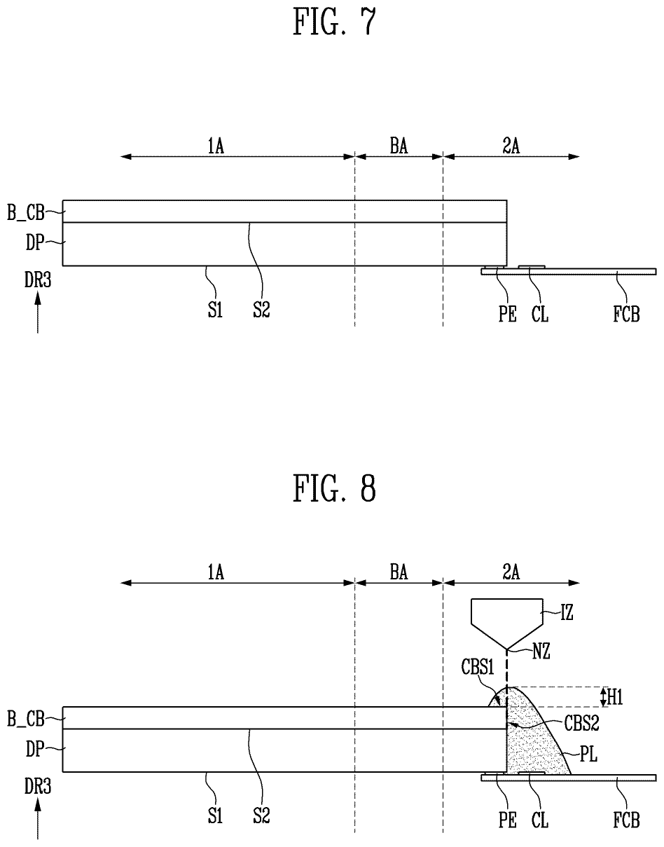

Hereinafter, a manufacturing method of the display device DD will be described with reference to FIGS. 6 to 12. Descriptions of content that is already provided above will be omitted. FIG. 6 is a schematic flowchart of a manufacturing method of a display device according to an embodiment. FIGS. 7 to 12 are schematic cross-sectional views of each process step according to a manufacturing method according to an embodiment.

Referring to FIG. 6, a manufacturing method of the display device DD may include attaching a base substrate to the display panel (S100), attaching the display panel DP and the flexible circuit board (S200), forming a protective layer on the flexible circuit board (S300), and removing a portion of the base substrate (S400).

Referring to FIG. 7, attaching the base substrate to the display panel (S100) may include attaching the base substrate B_CB to the second surface S2 of the display panel DP. The base substrate B_CB may contact the second surface S2 of the display panel DP. The base substrate B_CB may cover the second surface S2 of the display panel DP.

The base substrate B_CB may be attached to the back surface of the display panel DP to protect the display panel DP during the manufacturing process of the display device DD. The base substrate B_CB may be configured to protect the display panel DP and may be a substrate for forming the substrate CB. For example, during the manufacturing process of the display device DD, at least a portion of the base substrate B_CB may be removed, and the rest may remain in the display device DD to form the substrate CB.

The base substrate B_CB may be configured to protect a lower part of the display panel DP, and the time when the base substrate B_CB is attached to the display panel DP is not limited to a specific time. For example, the substrate B_CB may be attached before the display panel DP is manufactured or may be attached after the display panel DP is manufactured.

Attaching the display panel DP and the flexible circuit board (S200) may include forming or using a conductive adhesive layer PE to connect (or connect electrically) the display panel DP and the flexible circuit board FCB. The coating layer CL may be formed on the flexible circuit board FCB. The coating layer CL may cover at least a portion of the flexible circuit board FCB and protect a circuit formed on the flexible circuit board FCB.

Forming the conductive adhesive layer PE may involve disposing a conductive material on the first surface S1 of the display panel DP, disposing the flexible circuit board FCB on the conductive material, and connecting (or connecting electrically) the flexible circuit board FCB and the display panel DP by pressing at least one of the flexible circuit board FCB and the display panel DP toward each other.

The conductive material may be disposed in the second area 2A of the display panel DP, and the conductive material may be pressed to form the conductive adhesive layer PE. The conductive adhesive layer PE may electrically connect the flexible circuit board FCB and the display panel DP, and at least a portion of the flexible circuit board FCB and at least a portion of the display panel DP may be connected to each other.

Forming the protective layer PL on the flexible circuit board (S300) may involve applying a resin for forming the protective layer PL on the flexible circuit board FCB and curing the resin.

Referring to FIG. 8, applying resin to form the protective layer PL on the flexible circuit board FCB may entail applying the resin on the flexible circuit board FCB with a dispenser IZ. The resin may be applied through the dispenser IZ. The resin may be discharged onto the flexible circuit board FCB through the nozzle NZ of the dispenser IZ. The resin may include at least one of a thermosetting material or a photocuring material. However, the present disclosure is not limited thereto.

The process of applying the resin through the dispenser IZ may use at least one of a jet dispenser method, an inkjet method, and an one drop filling (ODF) method.

The position of the nozzle NZ of the dispenser IZ may align with one edge of the base substrate B_CB when viewed on a plane. Hence, the nozzle NZ of the dispenser IZ may be above a border of the base substrate B_CB when viewed on a plane. For example, the nozzle NZ of the dispenser IZ may overlap the border (or one edge) of the base substrate B_CB when viewed on a plane. One edge of the base substrate B_CB corresponding to the position of the nozzle NZ of the dispenser IZ may be an edge shared by the first substrate surface CBS1 and the second substrate surface CBS2. One edge of the base substrate B_CB corresponding to the position of the nozzle NZ of the dispenser IZ may be an edge parallel to the edge of the side surface of the display panel DP.

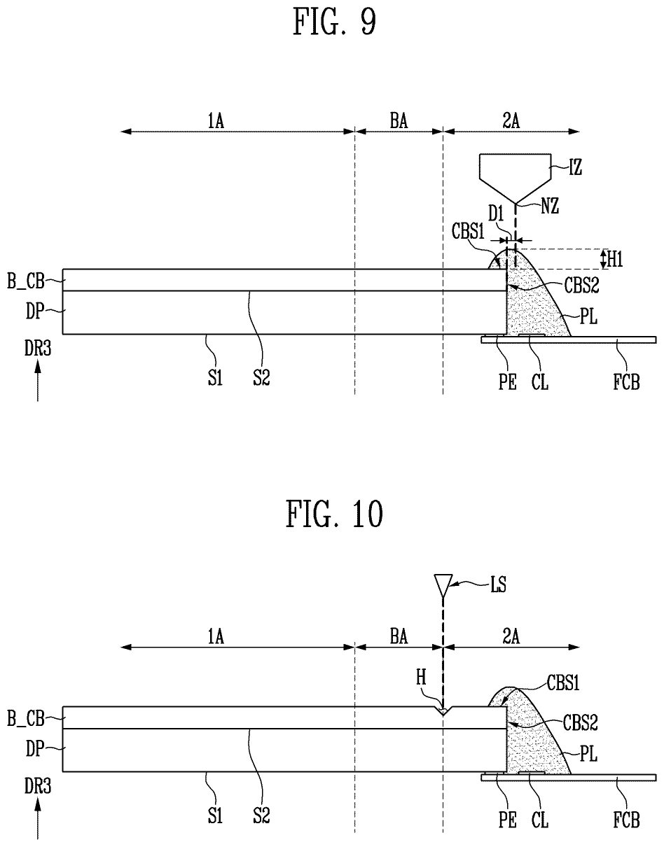

Alternatively, according to an embodiment, the nozzle NZ of the dispenser IZ may be disposed to have a straight distance of less than 100 μm (or less than 150 μm, according to an embodiment) from the edge shared by the first substrate surface CBS1 and the second substrate surface CBS2 to the direction extending along the second direction DR2 when viewed on a plane. For example, referring to FIG. 9, the nozzle NZ of the dispenser IZ and the edge shared by the first and second substrate surfaces CBS1 and CBS2 may be spaced apart from each other to have a straight distance d1 in the second direction DR2 when viewed on a plane. The straight distance d1 may be less than 100 μm or less than 150 μm.

The resin may be disposed on the first substrate surface CBS1 and the second substrate surface CBS2 of the base substrate B_CB. The resin may cover at least a portion of the first substrate surface CBS1 and the second substrate surface CBS2 of the base substrate B_CB. The resin may contact at least a portion of the first substrate surface CBS1 and the second substrate surface CBS2 of the base substrate B_CB. The resin may overlap the first substrate surface CBS1 of the base substrate B_CB when viewed on a plane. The resin may cover at least a portion of the flexible circuit board FCB and a side surface of the display panel DP. The first substrate surface CBS1 may be a surface opposite to a surface where the base substrate B_CB and the display panel DP contacts. The second substrate surface CBS2 may be a side surface of the base substrate B_CB.

The protective layer PL according to the present disclosure may be formed so that the resin covers at least a portion of the first substrate surface CBS1 of the base substrate B_CB and the second substrate surface CBS2 of the base substrate B_CB, and therefore prevents the conductive adhesive layer PE from being exposed to an outer area. Consequently, and the risk of foreign substances penetrating into a portion (e.g., the compression portion) where the conductive adhesive layer PE is disposed can be reduced.

The resin may be applied on the base substrate B_CB to form a bump having the protrusion height (H1). As depicted in FIG. 8, the protrusion height H1 is the distance between the first substrate surface CBS1 and the peak of the bump, the “peak” being the portion of the protective layer PL that is farthest from the flexible circuit board. The resin may be applied to have a higher height than the base substrate B_CB in the third direction DR3.

In curing the resin, the resin may be thermoset or photo-cured. However, the present disclosure is not limited thereto, and the resin may be cured naturally.

Referring to FIG. 10, the removal of a portion of the base substrate (S400) may include irradiating the bae substrate B_CB with a laser LS. The laser LS may be directed to a preselected area of the base substrate B_CB. For example, the laser LS may be directed to an area of the base substrate B_CB that lies on a boundary between the bending area BA and the second area 2A. However, the present disclosure is not limited thereto, and according to an embodiment, the laser may be directed to an area of the base substrate B_CB in the second area 2A when viewed on a plane.

The laser LS may be a CO2 laser, YAG laser, nano second laser, femto second laser, Bessel beam, Gaussian beam, or the like.

The laser LS may be directed to the base substrate B_CB to half-cut the base substrate B_CB. For example, the laser LS may be directed at the base substrate B_CB to form a groove H on the base substrate B_CB. According to an embodiment, a depth of the groove H may be less than half of a thickness of the base substrate B_CB. According to an embodiment, the depth of the groove H may be less than one-third of the thickness of the base substrate B_CB.

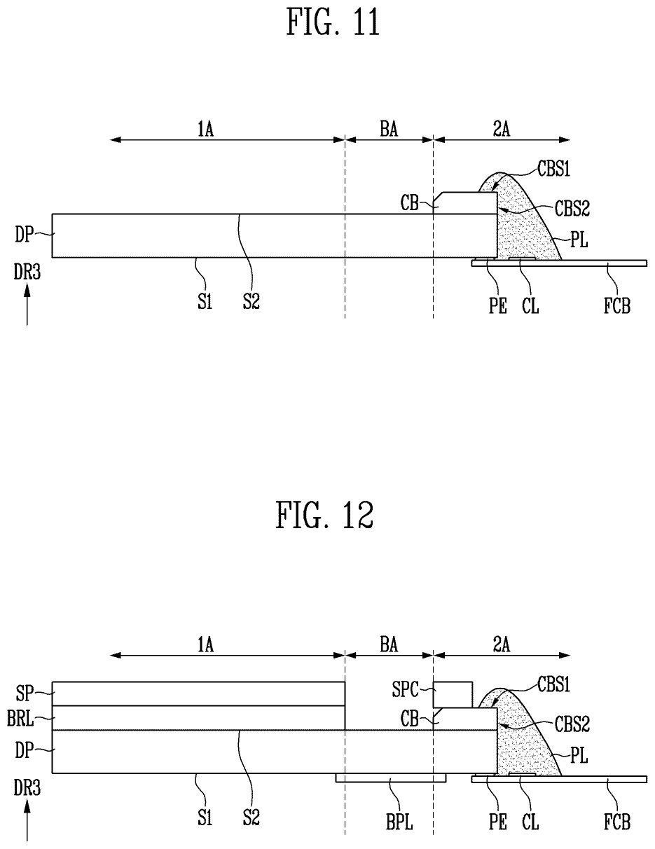

Referring to FIG. 11, in the removal of a portion of the base substrate (S400), at least a portion of the base substrate B_CB may be removed from the display panel DP. When viewed on a plane, the base substrate B_CB overlapping the first area 1A and the bending area BA may be removed from the display panel DP. At least a portion of the base substrate B_CB may be peeled off, leaving the remaining portion intact in the second area 2A. The base substrate B_CB may be partially removed to form the substrate CB disposed in the second area 2A, as depicted in FIG. 11.

When the base substrate B_CB is entirely removed, there is a risk that the protective layer PL may get removed (e.g., peeled off) along with the base substrate B_CB, causing foreign substances to enter a portion of the pad unit. In the manufacturing method of the display device DD according to the present disclosure, less than all of the base substrate B_CB may be removed. By leaving the portion of the base substrate B_CB that is covered by the protective layer PL intact, the risk of the protective layer PL being removed with the base substrate B_CB is reduced. By not compromising the protective layer PL, the risk of foreign substances entering a portion of the pad unit is reduced.

Referring to FIG. 12 in connection with FIG. 4, after the removal of a portion of the base substrate (S400), other configurations of the display device DD may be further formed. For example, the manufacturing method of the display device DD may further include forming a barrier layer BRL, a plate SP, a bending protective layer BPL, and a spacer SPC.

The barrier layer BRL may be formed on the second surface S2 of the display panel DP. The plate SP may be formed on the barrier layer BRL. The plate SP and the barrier layer BRL may not be disposed in the bending area BA and the second area 2A, but may be disposed in the first area 1A.

The bending protective layer BPL may be formed on the first surface S1 of the display panel DP. The bending protective layer BPL may be disposed in the bending area BA and a portion of the first and second areas A1 and A2.

The spacer SPC may be formed on the substrate CB. The spacer SPC may not contact the protective layer PL. The top of the spacer SPC may be further than the peak of protective layer PL from the first substrate surface CBS1 in the third direction DR3. The spacer SPC may have a greater height than the protective layer PL in the third direction DR3 from the first substrate surface CBS1. Accordingly, even if the display panel DP is bent, the protective layer PL and the plate SP may not contact each other (see FIG. 5).

Thereafter, the display panel DP may be bent along the bending area BA, and the adhesive layer AF and the cover member WD may be further formed to manufacture the display device DD shown in FIG. 5. Alternatively, the adhesive layer AF and the cover member WD may be attached before the display panel DP is bent.

As described above, while the present disclosure has been shown and described with reference to certain embodiments, it will be understood by those skilled in the art that various changes in forms and details may be made therein without departing from the spirit and scope of the present disclosure as defined by the appended claims and their equivalents.

Accordingly, the technical scope of the present disclosure may be determined by on the technical scope of the accompanying claims.

What is claimed is:

1. A display device comprising:
a display panel including a first surface and a second surface and displaying an image;
a substrate disposed on the second surface of the display panel and including a first substrate surface intersecting a side surface of the substrate;
a flexible circuit board connected to a portion of the display panel, the flexible circuit board comprising a pad unit;
a conductive adhesive layer electrically connecting the flexible circuit board and the display panel; and
a protective layer disposed on one surface of the flexible circuit board, wherein
the one surface of the flexible circuit board is a surface of the flexible circuit board facing the display panel, and
the protective layer covers at least a portion of the first substrate surface and the side surface.

2. The display device of claim 1, wherein
the display device includes a first area, a second area, and a bending area disposed between the first area and the second area,
the display panel is bendable in the bending area, and
the substrate is absent from the bending area.

3. The display device of claim 1, further comprising
a bending protective layer disposed on the first surface, wherein
at least a portion of the bending protective layer overlaps the substrate.

4. The display device of claim 1, wherein
the substrate contacts a portion of the second surface.

5. The display device of claim 4, wherein
the second surface is a surface opposite to a surface on which an image of the display panel is displayed.

6. The display device of claim 1, wherein
the conductive adhesive layer disposed on the one surface of the flexible circuit board,
the conductive adhesive layer contacts the flexible circuit board and the display panel,
the protective layer overlaps at least a portion of the conductive adhesive layer, and
the first substrate surface is a surface opposite to a surface of the substrate that contacts the display panel.

7. The display device of claim 1, wherein
the protective layer has a portion that extends from the flexible circuit board beyond the first substrate surface by a protrusion height, measured in a direction perpendicular to a plane on which the substrate is disposed.

8. The display device of claim 7, wherein
the protrusion height is no less than 20 μm and no greater than 60 μm.

9. The display device of claim 1, further comprising
a coating layer disposed on the one surface of the flexible circuit board, wherein
the protective layer covers at least a portion of the coating layer.

10. The display device of claim 1, further comprising
a spacer disposed on the first substrate surface, wherein
the spacer contacts less than all of the first substrate surface.

11. The display device of claim 8, further comprising
a spacer disposed on the first substrate surface and having a surface that extends farther from the first substrate surface than the protrusion height.

12. The display device of claim 1, further comprising
a barrier layer disposed on the second surface of the display panel; and
a plate disposed on the barrier layer and positioned to avoid contacting the protective layer.

13. A manufacturing method of a display device comprising:
providing a display panel having a first surface and a second surface;
attaching a base substrate to the second surface of a display panel, the base substrate having a first substrate surface and a side surface that intersect;
attaching a flexible circuit board to the display panel; and
forming a protective layer on the flexible circuit board, wherein
the forming the protective layer includes
applying resin on the flexible circuit board to cover at least a portion of the first substrate surface of the base substrate and the side surface of the base substrate.

14. The manufacturing method of claim 13, wherein
the display device includes a first area, a second area, and a bending area disposed between the first area and the second area, wherein the display panel is bendable in the bending area,
the second surface is a surface opposite to a surface on which an image of the display panel is displayed,
the first substrate surface is a surface of the substrate that is opposite to a surface that contacts the display panel, and
attaching the base substrate comprises putting the base substrate in contact with the second surface of the display panel.

15. The manufacturing method of claim 13, further comprising
using a dispenser to apply the resin, and
positioning a nozzle of the dispenser to align with a plane of the side surface.

16. The manufacturing method of claim 13, further comprising
using a dispenser to apply the resin, and
positioning a nozzle of the dispenser to be spaced apart from a plane of the side surface by less than 150 km.

17. The manufacturing method of claim 14, further comprising
removing at least a portion of the base substrate by irradiating the base substrate with a laser, and
directing the laser at either a boundary between the bending area and the second area or the second area.

18. The manufacturing method of claim 17, further comprising forming
a groove on the base substrate with the laser, wherein a depth of the groove is less than half of a thickness of the base substrate.

19. The manufacturing method of claim 14, further comprising
removing less than all of the base substrate, and leaving a
portion of the base substrate intact in the second area.

20. The manufacturing method of claim 19, further comprising
forming a spacer on the base substrate that remains in the second area, such that
the spacer covers a different portion of the base substrate from the protective layer.
